(19) United States
(12) Patent Application Publication
(10) Pub. No.: US 2011/0298003 A1
(43) Pub. Date: Dec. 8, 2011

(54) EPOXY RESIN COMPOSITION FOR OPTICAL USE, OPTICAL COMPONENT USING THE SAME, AND OPTICAL SEMICONDUCTOR DEVICE OBTAINED USING THE SAME

(75) Inventors: Takahiro UCHIDA, Osaka (JP); Hiroshi NORO, Osaka (JP); Toshimichi SUZUKI, Osaka (JP)

(73) Assignee: NITTO DENKO CORPORATION, Osaka (JP)

(21) Appl. No.: 13/153,570

(22) Filed: Jun. 6, 2011

(30) Foreign Application Priority Data
Jun. 7, 2010 (JP) 2010-130344

(51) Int. Cl. H01L 33/52; C08K 3/40; C08K 3/36; C08L 63/00

(52) U.S. Cl. 257/100; 523/400; 523/466; 257/E33.059

(57) ABSTRACT

The present invention relates to an epoxy resin composition for optical use including the following ingredients (A) to (C): (A) an epoxy resin; (B) a curing agent; and (C) an inorganic filler including (c1) an inorganic filler having a refractive index larger than a refractive index of a cured product obtained from the ingredients of the epoxy resin composition excluding the (C) inorganic filler and (c2) an inorganic filler having a refractive index smaller than the refractive index of the cured product obtained from the ingredients of the epoxy resin composition excluding the (C) inorganic filler.

### FIELD OF THE INVENTION

The present invention relates to an epoxy resin composition for optical use which is used for resin encapsulation of optical semiconductor elements such as light emitting elements and light receiving sensors and also as a material for forming various optical components, and relates to an optical component using the same and an optical semiconductor device obtained using the same.

### BACKGROUND OF THE INVENTION

Resin compositions for optical semiconductor element encapsulation to be used at the resin encapsulation of optical semiconductor elements such as light emitting elements and light receiving sensors are required to have transparency to a cured product serving as a resin encapsulating portion. Therefore, epoxy resin compositions obtained using an epoxy resin such as a bisphenol A type epoxy resin and a curing agent such as an acid anhydride have hitherto been used for various purposes.

As technologies for imparting light diffusibility of a resin composition for optical semiconductor element encapsulation and also enhancing mechanical physical properties, there is proposed a technique for filling a light diffusing material and an inorganic filler such as a transparent glass filler (see Patent Document 1). The foregoing technique is concerned with a technique for controlling the transparency or light diffusion characteristics while utilizing a difference between a refractive index of a cured product composed only of an inorganic filler-free resin ingredient and a refractive index of an inorganic filler.

On the other hand, there is proposed a material including a light diffusing pressure-sensitive adhesive layer formed by dispersing and containing an organic filler such as an acrylic resin and a styrene resin in an acrylic pressure-sensitive adhesive serving as a binder (see Patent Document 2).

Patent Document 1: JP-A-2007-154064

Patent Document 2: JP-A-2008-116879

### SUMMARY OF THE INVENTION

However, in the inorganic filler-containing resin composition for optical semiconductor element encapsulation utilizing a refractive index difference as disclosed in the foregoing Patent Document 1, in its use temperature region, a fluctuation in refractive index of the cured product composed only of an organic ingredient is larger than a fluctuation in refractive index of the inorganic filler, so that there was involved such a problem that the transmittance and light dispersibility of the resin composition cured product largely vary depending upon a temperature condition. For that reason, for example, in the case of resin encapsulating an optical semiconductor element using the foregoing resin composition, there is involved such a problem that the light receiving sensitivity of the optical semiconductor element changes depending upon the temperature condition, so that the stability of a product is deteriorated.

Also, in the foregoing Patent Document 2, for example, a usable temperature of the light diffusing pressure-sensitive adhesive layer lies in the vicinity of room temperature as high as from 10 to 40° C. in view of its constituent ingredients, and in the case of taking into consideration the use for encapsulation of an optical semiconductor element, there is involved such a problem that in a high-temperature region such as a molding temperature and a reflow temperature, the organic filler is softened or melted, so that it is difficult to obtain the desired effects.

Under such circumstances, the invention has been made, and an object thereof is to provide an epoxy resin composition for optical use with a small temperature dependency of light transmittance and capable of reducing a fluctuation in light transmittance against the temperature, an optical component using the same, and an optical semiconductor device obtained using the same.

Namely, the present invention relates to the following items (1) to (10).

(1) An epoxy resin composition for optical use, including the following ingredients (A) to (C):

(A) an epoxy resin;

(B) a curing agent; and

(C) an inorganic filler including (c1) an inorganic filler having a refractive index larger than a refractive index of a cured product obtained from the ingredients of the epoxy resin composition excluding the (C) inorganic filler and (c2) an inorganic filler having a refractive index smaller than the refractive index of the cured product obtained from the ingredients of the epoxy resin composition excluding the (C) inorganic filler.

(2) The epoxy resin composition for optical use according to (1), in which the inorganic filler (C) is an inorganic filler including (c1) an inorganic filler having a refractive index larger by from 0.01 to 0.10 than the refractive index of the cured product obtained from the ingredients of the epoxy resin composition excluding the (C) inorganic filler and (c2) an inorganic filler having a refractive index smaller by from 0.02 to 0.15 than the refractive index of the cured product obtained from the ingredients of the epoxy resin composition excluding the (C) inorganic filler.

(3) The epoxy resin composition for optical use according to (1) or (2), in which a maximum refractive index difference among the plural inorganic fillers constituting the inorganic filler (C) is 0.15 or less.

(4) The epoxy resin composition for optical use according to any one of (1) to (3), in which a mixing weight ratio of the inorganic filler (c1) and the inorganic filler (c2) is from 17/83 to 80/20 in terms of (c1)/(c2).

(5) The epoxy resin composition for optical use according to any one of (2) to (4), in which the inorganic filler (c1) having a refractive index larger by from 0.01 to 0.10 than the refractive index of the cured product obtained from the ingredients of the epoxy resin composition excluding the (C) inorganic filler is a glass powder; and the inorganic filler (c2) having a refractive index smaller by from 0.02 to 0.15 than the refractive index of the cured product obtained from the ingredients of the epoxy resin composition excluding the (C) inorganic filler is a silica powder.

(6) The epoxy resin composition for optical use according to any one of (1) to (5), in which a use temperature region of the epoxy resin composition for optical use is from −40 to 150° C.

(7) The epoxy resin composition for optical use according to (1), the inorganic filler (c1) having a refractive index larger than a refractive index of the cured product obtained from the ingredients of the epoxy resin composition excluding the (C) inorganic filler is a glass powder.

(8) The epoxy resin composition for optical use according to (1), the inorganic filler (c2) having a refractive index smaller than the refractive index of the cured product obtained from the ingredients of the epoxy resin composition excluding the (C) inorganic filler is a silica powder.

(9) An optical component obtained by curing the epoxy resin composition for optical use according to any one of (1) to (8).

(10) An optical semiconductor device manufactured by subjecting an optical semiconductor element to resin encapsulation using the epoxy resin composition for optical use according to any one of (1) to (8).

For the purpose of obtaining an epoxy resin composition for optical use with a small temperature dependency of light transmittance, the present inventors made extensive and intensive investigations. Then, the present inventors paid attention to a difference between a refractive index of a cured product obtained from an organic ingredient and a refractive index of an inorganic filler that is a blending ingredient, and from a different point of view from the conventional epoxy resin compositions utilizing a refractive index difference, they again made investigations on the refractive index difference therebetween from various viewpoints. Then, on the basis of the fact that in general, a fluctuation in refractive index of a cured product obtained from an organic ingredient with a change of temperature is different from a fluctuation in refractive index of an inorganic filler with a change of temperature, and therefore, a fluctuation in refractive index difference with a change of temperature is generated in a combination with a single kind of inorganic filler (namely, in the fluctuation in refractive index with a change of temperature, although the fluctuation in refractive index of the inorganic ingredient is small, a change of refractive index is generated in a cured product obtained from an organic ingredient), the present inventors made further investigations on this point. As a result, it has been found that in view of the fact that it is difficult to suppress the fluctuation in refractive index with a change of temperature in the cured product per se obtained from an organic ingredient, for the purpose of contriving to stabilize the temperature dispersibility of light transmittance using an inorganic filler having a specified refractive index, when two kinds of inorganic fillers having a different refractive index from each other, namely, (c1) an inorganic filler having a refractive index larger than a refractive index of a cured product obtained from an organic ingredient and (c2) an inorganic filler having a refractive index smaller than a refractive index of a cured product obtained from an organic ingredient, are used, it becomes possible to suppress a fluctuation in refractive index due to a temperature change of the whole of a system of an epoxy resin composition, whereby an epoxy resin composition with a small fluctuation in refractive index, which is small in a so-called temperature dependency of refractive index, is obtained, leading to accomplishment of the invention.

In the light of the above, the invention is concerned with an epoxy resin composition for optical use including an inorganic filler [ingredient (C)] including (c1) an inorganic filler having a refractive index larger than a refractive index of a cured product obtained from the ingredients of the epoxy resin composition excluding the (C) inorganic filler and (c2) an inorganic filler having a refractive index smaller than the refractive index of the cured product obtained from the ingredients of the epoxy resin composition excluding the (C) inorganic filler. For that reason, the temperature dependency of light transmittance upon from an ultraviolet light region to a visible light region becomes small, and when the epoxy resin composition for optical use of the invention is used as an optical component forming material or an encapsulating material of optical semiconductor devices, it is possible to provide a stable product with high reliability.

Then, when a mixing weight ratio of the inorganic filler (c1) having a refractive index larger than a refractive index of a cured product obtained from the ingredients of the epoxy resin composition excluding the (C) inorganic filler and the inorganic filler (c2) having a refractive index smaller than the refractive index of the cured product obtained from the ingredients of the epoxy resin composition excluding the (C) inorganic filler is set to a specified range, the temperature dependency of light transmittance becomes smaller, and hence, such is effective.

### DETAILED DESCRIPTION OF THE INVENTION

The epoxy resin composition for optical use (hereinafter also referred to as “epoxy resin composition”) of the invention is a composition obtained using an epoxy resin (ingredient A), a curing agent (ingredient B) and a specified inorganic filler (ingredient C), and it is usually supplied for an encapsulating material in a liquid or powder state or in the form of a tablet obtained by tableting the powder.

Examples of the epoxy resin (ingredient A) include a bisphenol A type epoxy resin, a bisphenol F type epoxy resin, a novolak type epoxy resin such as a phenol novolak type epoxy resin and a cresol novolak type epoxy resin, an alicyclic epoxy resin, a nitrogenous ring-containing epoxy resin such as triglycidyl isocyanurate and a hydantoin epoxy resin, a hydrogenated bisphenol A type epoxy resin, an aliphatic epoxy resin, a glycidyl ether type epoxy resin, a bisphenol S type epoxy resin, a biphenyl type epoxy resin which is the main stream of a curing type with a low water absorption, a dicyclic type epoxy resin and a naphthalene type epoxy resin. Such an epoxy resin is used alone or in combination of two or more kinds thereof. Among these epoxy resins, it is preferable to use an alicyclic epoxy resin (for example, CELLOXIDE 2021P and CELLOXIDE 2081, both of which are manufactured by Daicel Chemical Industries, Ltd.) or triglycidyl isocyanurate alone or in combination from the standpoints of excellent transparency and discoloration resistance of a cured product.

The epoxy resin (ingredient A) may be solid or liquid at room temperature. In general, however, it is preferable to use an epoxy resin having an average epoxy equivalent of from 90 to 1,000. Also, in the case of a solid epoxy resin, one having a softening point of 160° C. or less is preferable. That is, this is because when the epoxy equivalent is too small, there is a concern that the epoxy resin composition cured product becomes brittle; whereas when the epoxy equivalent is too large, there is a tendency that a glass transition temperature (Tg) of the epoxy resin composition cured product becomes low.

As the curing agent (ingredient B) which is used together with the ingredient A, an acid anhydride is preferably used. Examples of the acid anhydride include phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, methylhexahydrophthalic anhydride and methyltetrahydrophthalic anhydride. Such an acid anhydride curing agent can be used alone or in combination of two or more kinds thereof. Among these acid anhydride curing agents, it is preferable to use phthalic anhydride, hexahydrophthalic anhydride, tetrahydrophthalic anhydride or methylhexahydrophthalic acid alone or in combination of two or more kinds thereof. Furthermore, the acid anhydride curing agent (ingredient B) is preferably one having a molecular weight of from about 140 to 200 is preferable. Also, a colorless or pale yellow acid anhydride curing agent is preferable.

A blending proportion of the epoxy resin (ingredient A) and the curing agent (ingredient B) is set such that the amount of an active group (an acid anhydride group or a hydroxyl group) capable of reacting with an epoxy group in the curing agent (ingredient B) is preferably from 0.5 to 1.5 equivalents, and more preferably from 0.7 to 1.2 equivalents per equivalent of an epoxy group in the epoxy resin (ingredient A). That is, this is because when the amount of the active group is too small, there is a tendency that not only a curing rate of the epoxy resin composition becomes slow, but a glass transition temperature (Tg) of a cured product thereof becomes low; whereas when the amount of the active group is too large, there is a tendency that the humidity resistance is lowered.

Also, an epoxy resin based curing agent other than the acid anhydride, for example, a phenol based curing agent, an amine based curing agent, a curing agent obtained by partially esterifying the acid anhydride curing agent with an alcohol, or a curing agent of a carboxylic acid such as hexahydrophthalic acid, tetrahydrophthalic acid and methylhexahydrophthalic acid may be used alone, or a combination of the foregoing acid anhydride curing agent and phenol based curing agent may be used as the curing agent (ingredient B) according to the purpose and applications thereof. For example, when a curing agent of a carboxylic acid is used in combination, the curing rate can be increased, and the productivity can be enhanced. In this connection, even in the case of using such a curing agent, its blending proportion may be the same as the foregoing blending proportion (equivalent ratio).

The specified inorganic filler (ingredient C) which is used together with the ingredient A and ingredient B is one including an inorganic filler provided with at least two kinds of refractive indexes of (c1) an inorganic filler having a refractive index larger than a refractive index of a cured product obtained from the ingredients of the epoxy resin composition excluding the (C) inorganic filler and (c2) an inorganic filler having a refractive index smaller than the refractive index of the cured product obtained from the ingredients of the epoxy resin composition excluding the (C) inorganic filler.

In such a specified inorganic filler (ingredient C), examples of materials thereof include a silica powder such as a crystalline silica powder and a fused silica powder, a glass powder containing B₂O₃ in SiO₂, barium sulfate, an alumina powder, zinc oxide and boron nitride. Such an inorganic filler is used alone or in combination of two or more kinds thereof. Such an inorganic filler is properly discriminated and used depending upon the refractive index which it has itself.

Examples of the inorganic filler (c1) (hereinafter also referred to as “high-refractive index inorganic filler”) having a refractive index larger than a refractive index of a cured product obtained from the ingredients of the epoxy resin composition excluding the (C) inorganic filler include a glass powder containing SiO₂ as a main component. More specifically, a glass powder containing SiO₂ as a main component and containing Al₂O₃, CaO, Ba₂O₃, ZrO and ZnO as constituent ingredients together with Si0₂ is exemplified. Such a high-refractive index inorganic filler (c1) may be constituted of a single material or plural materials. Specifically, as the high-refractive index inorganic filler (c1), one having a value (namely, a refractive index difference) larger by from 0.01 to 0.10 than a refractive index of a cured product obtained from the ingredients of the epoxy resin composition excluding the (C) inorganic filler is preferably used, and one having a value larger by from 0.01 to 0.05 than a refractive index of a cured product obtained from the ingredients of the epoxy resin composition excluding the (C) inorganic filler is more preferably used. That is, this is because when the refractive index difference is too small, the refractive index of the inorganic filler is gathered in its temperature region relative to a change of refractive index of ingredients excluding an inorganic filler in the use temperature region, and there is a tendency that the light transmittance and light dispersibility vary dependent upon the temperature; whereas when the refractive index difference is too large, there is a tendency that it is difficult to obtain a favorable light transmittance at each wavelength.

Examples of the inorganic filler (c2) (hereinafter also referred to as “low-refractive index inorganic filler”) having a refractive index smaller than a refractive index of a cured product obtained from the ingredients of the epoxy resin composition excluding the (C) inorganic filler include a silica powder such as a crystalline silica powder and a fused silica powder. Such a low-refractive index inorganic filler (c2) may be constituted of a single material or plural materials. Specifically, as the low-refractive index inorganic filler (c2), one having a value (namely, a refractive index difference) smaller by from 0.02 to 0.15 than a refractive index of a cured product obtained from the ingredients of the epoxy resin composition excluding the (C) inorganic filler is preferably used, and one having a value smaller by from 0.02 to 0.07 than a refractive index of a cured product obtained from the ingredients of the epoxy resin composition excluding the (C) inorganic filler is more preferably used. That is, this is because when the refractive index difference is too small, the refractive index of the inorganic filler is gathered in its temperature region relative to a change of refractive index of ingredients excluding an inorganic filler in the use temperature region, and there is a tendency that the light transmittance and light dispersibility vary dependent upon the temperature; whereas when the refractive index difference is too large, there is a tendency that it is difficult to obtain a favorable light transmittance at each wavelength.

In this way, at the combination of the high-refractive index inorganic filler (c1) and the low-refractive index inorganic filler (c2), a refractive index difference between the highest refractive index of the high-refractive index inorganic filler (c1) and the lowest reflective index of the low-refractive index inorganic filler (c2) is set preferably to 0.15 or less, more preferably to the range of from 0.02 to 0.15, and especially preferably to the range of from 0.02 to 0.07. That is, this is because when the refractive index difference is too small, the refractive index of the inorganic filler is gathered in its temperature region relative to a change of refractive index of ingredients excluding an inorganic filler in the use temperature region, and there is a tendency that the light transmittance and light dispersibility vary dependent upon the temperature; whereas when the refractive index difference is too large, there is a tendency that it is difficult to obtain a favorable light transmittance at each wavelength.

A mixing weight ratio of the high-refractive index inorganic filler (c1) and the low-refractive index inorganic filler (c2) is set preferably to the range of from 17/83 to 80/20, and especially preferably to the range of from 20/80 to 73/27 in terms of (c1)/(c2). When the mixing weight ratio of the high-refractive index inorganic filler (c1) and the low-refractive index inorganic filler (c2) is set to the foregoing ranges, the temperature dependency of light transmittance becomes much smaller, and hence, such is effective.

As such a specified inorganic filler (ingredient C), one having an average particle size in the range of from 1 to 50 μm is preferably used, and one having an average particle size in the range of from 15 to 30 μm is especially preferably used. Also, a maximum particle size of the specified inorganic filler (ingredient C) is preferably 75 μm or less, and especially preferably 45 μm or less. That is, this is because when the maximum particle size of the specified inorganic filler (ingredient C) is too large, for example, there is a tendency that a fault such as gate clogging at the time of molding is caused. The average particle size and maximum particle size can be, for example, measured using a laser diffraction/scattering particle size distribution analyzer.

A content of such a specified inorganic filler (ingredient C) is set preferably to the range of from 5.0 to 80% by weight, and especially preferably to the range of from 7.0 to 50% by weight of the whole of the epoxy resin composition. That is, this is because when the content of the specified inorganic filler (ingredient C) is too small, there is a tendency that it is difficult to obtain a reducing effect of the temperature dependency of refractive index; whereas when the content of the specified inorganic filler (ingredient C) is reversely too large, there is a tendency that the light transmittance becomes low, so that cloudiness of a cured product is generated.

In this way, by dispersing in the epoxy resin composition the specified inorganic filler (ingredient C) having a refractive index different from a refractive index of a cured product obtained from the ingredients of the epoxy resin composition excluding the (C) inorganic filler, light is scattered, and hence, a linear light transmittance is lowered. In general, the linear light transmittance of a material having moderate light scattering properties is from about 10 to 50%. When this linear light transmittance is low, for example, so far as a light emitting element is concerned, the directivity is deteriorated, and so far as a light receiving element is concerned, the light receiving sensitivity is lowered. On the other hand, when the linear light transmittance is high so that the light scattering is insufficient, for example, so far as a light emitting element is concerned, the desired light scattering is not obtained, and so far as a light receiving element is concerned, the light receiving sensitivity is too strong.

Furthermore, the epoxy resin composition of the invention can be blended with, in addition to the foregoing ingredients A to C, various additives such as a curing accelerator, an anti-deterioration agent, a modifier, a silicone compound, a defoaming agent, a leveling agent, a release agent, a dye and a pigment, accordingly.

Examples of the curing accelerator include tertiary amines such as 1,8-diaza-bicyclo[5.4.0]undecene-7, triethylenediamine, tri-2,4,6-dimethylaminomethylphenol and N,N-dimethylbenzylamine, imidazoles such as 2-ethyl-4-methylimidazole and 2-methylimidazole, phosphorus compounds such as triphenylphosphine, tetraphenylphosphonium tetraphenylborate and tetra-n-butylphosphonium-o,o-diethyl phosphorodithioate, quaternary ammonium salts, organic metal salts and derivatives thereof. Such a curing accelerator is used alone or in combination of two or more kinds thereof. Of these curing accelerators, an octylic acid salt or phosphonium salt of a tertiary amine such as 1,8-diaza-bicyclo[5.4.0]undecene-7 and tri-2,4,6-dimethylaminomethylphenol is more suitably used.

A content of the curing accelerator is set preferably to from 0.01 to 8.0 parts by weight, and more preferably to from 0.1 to 3.0 parts by weight based on 100 parts by weight of the epoxy resin (ingredient A). That is, this is because when the content of the curing accelerator is too small, there is a concern that the sufficient curing accelerating effect is not obtained; whereas when the content of the curing accelerator is too large, there is a tendency that the resulting cured product is discolored.

Examples of the anti-deterioration agent include anti-deterioration agent such as phenol based compounds, amine based compounds, organic sulfur based compounds and phosphine based compounds.

Examples of the modifier include various modifiers such as glycols, for example, ethylene glycol, silicones and alcohols.

Examples of the defoaming agent include various defoaming agents such as silicone based compounds.

The silicone compound is used for the purpose of obtaining higher light resistance than the epoxy resin, and in recent years, epoxy-modified silicone resins and complex materials having an epoxy resin and a silicone resin complexed therein receives attention as an encapsulating resin material with high light resistance.

Among them, examples of the preferred silicone compound include those in which a siloxane unit serving as a constituent ingredient thereof is represented by the following general formula (1).

Rₘ(OR¹)ₙSiO_{(4-m-n/2} (1)

In the formula (1), R represents a substituted or unsubstituted, saturated monovalent hydrocarbon group having from 1 to 18 carbon atoms, and Rs may be the same or different from each other; R¹ represents a hydrogen atom or an alkyl group having from 1 to 6 carbon atoms, and R¹s may be the same or different from each other; and each of m and n represents an integer of from 0 to 3.

Examples of such a silicone compound include those which have at least one silicon atom-bonded hydroxyl group or alkoxy group in one molecule thereof and in which 10% by mole or more of the silicon atom-bonded monovalent hydrocarbon group (R) is occupied by a substituted or unsubstituted aromatic hydrocarbon group.

As for the substituted or unsubstituted, saturated monovalent hydrocarbon group having from 1 to 18 carbon atoms represented by R in the formula (1), specific examples of the unsubstituted saturated monovalent hydrocarbon group include linear or branched alkyl groups such as a methyl group, an ethyl group, a propyl group, an isopropyl group, an n-butyl group, an isobutyl group, a t-butyl group, a pentyl group, an isopentyl group, a hexyl group, an isohexyl group, a heptyl group, an isoheptyl group, an octyl group, an isooctyl group, a nonyl group and a decyl group; cycloalkyl groups such as a cyclopentyl group, a cyclohexyl group, a cyclooctyl group, a dicyclopentyl group and a decahydronaphthyl group; and aromatic groups such as aryl groups, for example, a phenyl group, a naphthyl group, a tetrahydronaphthyl group, a tolyl group and an ethylphenyl group, and aralkyl groups, for example, a benzyl group, a phenylethyl group, a phenylpropyl group and a methylbenzyl group.

On the other hand, as for R in the formula (1), examples of the substituted saturated monovalent hydrocarbon group include hydrocarbon groups in which a part or all of the hydrogen atoms are substituted with a halogen atom, a cyano group, an amino group, an epoxy group or the like. Specific examples thereof include substituted hydrocarbon groups such as a chloromethyl group, a 2-bromoethyl group, a 3,3,3-trifluoropropyl group, a 3-chloropropyl group, a chlorophenyl group, a dibromophenyl group, a difluorophenyl group, a β-cyanoethyl group, a γ-cyanopropyl group and a β-cyanopropyl group.

Also, (OR¹) of the formula (1) is a hydroxyl group or an alkoxy group. When (OR¹) is an alkoxy group, specific examples of R¹ include the alkyl groups having from 1 to 6 carbon atoms as enumerated above for R. More specific examples of R¹ include a methyl group, an ethyl group and an isopropyl group. These groups may be the same or different from each other in the same siloxane unit or among the siloxane units.

A content of the silicone compound is set preferably to the range of from 5 to 60% by weight of the whole of the epoxy resin composition. Taking into consideration the fact that a linear expansion coefficient thereof becomes large, the content of the silicone compound is especially preferably in the range of from 10 to 40% by weight. That is, this is because when the content of the silicone compound is too small, there is a tendency that the heat resistance and light degradation resistance are lowered; whereas when the content of the silicone compound is too large, there is a tendency that the brittleness of the resulting epoxy resin composition cured product per se becomes remarkable.

Also, when the optical semiconductor device of the invention is a light emitting device capable of emitting light with a wavelength in ultraviolet light to blue regions, by dispersing a phosphor as a wavelength converter in the epoxy resin composition or by disposing it in the vicinity of a light emitting element, it is possible to form the optical semiconductor device of the invention as a device capable of emitting white light.

The epoxy resin composition of the invention can be, for example, obtained in a liquid or powder state or in the form of a tablet obtained by tableting the powder in the following manufacturing manner. That is, in order to obtain an epoxy resin composition in a liquid state, for example, the liquid is obtained by properly blending the foregoing respective blending ingredients. Also, in order to obtain an epoxy resin composition in a powder state or in the form of a tablet obtained by tableting the powder, for example, after properly blending and preliminarily mixing the foregoing respective blending ingredients, the mixture is kneaded using a kneader to achieve melt mixing. Subsequently, the molten mixture is cooled to room temperature, subjected to an aging step and then pulverized by known means, whereby an epoxy resin composition in a powder state can be manufactured. Furthermore, if desired, it is possible to tablet the epoxy resin composition in a powder state, thereby converting it into a tablet.

The thus-obtained epoxy resin composition of the invention is, for example, cured in a desired shape and utilized as an optical component for light scattering. It may be said that the epoxy resin composition of the invention is suitable for optical products to be used in places where a change of temperature is vigorous because its cured product is reduced with respect to a fluctuation in light transmittance by the temperature.

Also, as for the utilization of the epoxy resin composition of the invention as an encapsulating material for an optical semiconductor element, when the epoxy resin composition of the invention is used as an encapsulating material for light emitting device (LED), the directivity of diffusion and irradiation of light from LED is not influenced by a temperature increase due to the heat generation of LED but becomes constant, so that it may be said that such is suitable as a light source. On the other hand, when the epoxy resin composition of the invention is used as an encapsulating material for light receiving element, in view of the facts that an incident light angle range where the light can be received can be made wide and that the light receiving intensity is hardly influenced by the surrounding temperature, a light receiving device with excellent reliability is obtainable. Also, when the sensitivity of the light receiving element is very high, even if laser light or the like is made incident, the light is scattered. Thus, the light is scattered over the whole of the light receiving element surface, so that such is effective for preventing the degradation of the light receiving element from occurring.

The thus obtained epoxy resin composition of the invention is, for example, used as an encapsulating material for optical semiconductor elements such as a light emitting device (LED), a sensor of every sort and a charge coupling device (CCD), or a forming member for optical semiconductor devices. That is, in order to encapsulate an optical semiconductor element using the epoxy resin composition of the invention, for example, the encapsulation can be performed according to an optical semiconductor element encapsulation method such as transfer molding, injection molding, potting, coating and casting. In this connection, when the epoxy resin composition of the invention is in a liquid state, a so-called two-liquid type in which at least the epoxy resin and the curing accelerator are individually separated and stored, and the both are mixed just before the use may be adopted. Also, when the epoxy resin composition of the invention is subjected to a prescribed aging step and then formed in a powder state or tablet form, at the melt mixing of the foregoing respective blending ingredients, the mixture may be formed into a B-stage state (semi-cured state) and heat melted at the time of use.

The optical semiconductor device obtained using the epoxy resin composition of the invention can be manufactured by subjecting an optical semiconductor element to resin encapsulation in the way described above. In this connection, as for the molding condition (curing condition of the epoxy resin composition), there is exemplified a condition under which the epoxy resin composition of the invention is heat cured at from 130 to 180° C. for from 2 to 8 minutes and then post-cured at from 130 to 180° C. for from 1 to 5 hours. Also, a curing condition of the epoxy resin composition at the preparation of an optical component is the same as the condition described above.

Specifically, as for the use temperature region in various applications of the epoxy resin composition of the invention, a temperature region of from −40 to 150° C. is referred to herein. In such a temperature region, the temperature dependency of light transmittance of the epoxy resin composition cured product is small, and a fluctuation of light transmittance against the temperature is reduced.

Also, the light transmittance as referred to in the invention means a light transmittance against a wavelength in from an ultraviolet light region to a visible light region. Specifically, the terms “from an ultraviolet light region to a visible light region” mean a range of wavelength of from 300 to 800 nm.

### EXAMPLES

Next, Examples are described along with Comparative Examples. However, it should not be construed that the invention is limited to these Examples.

First of all, prior to the preparation of an epoxy resin composition, the following respective ingredients were arranged and prepared.

### [Epoxy Resin]

Triglycidyl isocyanurate (epoxy equivalent: 100 g/eq, melting point: 100° C.)

### [Acid Anhydride]

Methylhexahydrophthalic anhydride (acid equivalent: 165 g/eq)

### [Silicone Compound]

206 g (50% by mole) of phenyltrimethoxysilane and 126 g (50% by mole) of dimethyldimethoxysilane were charged in a flask, and a mixture of 1.2 g of a 20% HCl aqueous solution and 40 g of water was added dropwise thereto. After completion of the dropwise addition, refluxing was continued for one hour. Subsequently, the reaction solution was cooled to room temperature (25° C.) and then neutralized with a sodium hydrogencarbonate solution. The resulting organosiloxane solution was filtered to remove impurities, and a low-boiling material was distilled off under reduced pressure using a rotary evaporator, thereby obtaining a silicone compound in a liquid state. The resulting silicone compound had a softening point of 59° C. and a hydroxyl group concentration of 5.1% by mole. Furthermore, the resulting silicone compound contained an OH group and an alkoxy group, as reduced into the OH group, of 9% by weight.

### [Curing Accelerator]

Octylic acid salt of 1,8-diaza-bicyclo[5.4.0]undecene-7

### [Inorganic Filler A]

Light diffusing material (silica powder): spherical fused silica powder containing, as a main component, SiO₂ having a maximum particle size of 20 μm or less and an average particle size of 3 μm (refractive index: 1.45)

### [Inorganic Filler B]

Spherical glass powder having a maximum particle size of 45 μm and an average particle size of 15 μm [refractive index: 1.55, composition and composition ratio (% by weight): SiO₂/Al₂O₃/CaO/B₂O₃/ZrO/ZnO=44/15/13/20/5/3]

### [Inorganic Filler C]

Spherical glass powder having a maximum particle size of 45 μm and an average particle size of 15 μm [refractive index: 1.52, composition and composition ratio (% by weight): SiO₂/Al₂O₃/CaO/B₂O₃/ZrO/ZnO=49.5/20/2.5/20/5/3]

### Examples 1 to 6 and Comparative Examples 1 to 6

Respective ingredients shown in each of the following Tables 1 and 2 were blended in a proportion shown in each of those tables and melt mixed (at 135° C.) in a beaker, and after aging, the resultant was cooled for solidification at room temperature (25° C.) and then pulverized to prepare a desired epoxy resin composition in a fine powder state. In this connection, with regard to the epoxy resin composition, a refractive index of a cured product obtained from the ingredients (organic ingredients) excluding the (C) inorganic fillers was 1.51. The foregoing refractive index of the cured product is a value obtained by: preparing a cured product (50 mm in diameter×1 mm in thickness) obtained from the foregoing organic ingredients by curing at 150° C. for 4 minutes and then after-curing at 150° C. for 3 hours; and measuring its refractive index at 589.3 nm using an Abbe's refractometer, manufactured by Atago Co., Ltd. Also, a refractive index of each of the foregoing inorganic fillers is a value obtained by measuring its refractive index at 589.3 nm using an Abbe's refractometer, manufactured by Atago Co., Ltd.

By using each of the thus-obtained epoxy resin compositions of the Examples and Comparative Examples, the temperature dependency of light transmittance at each of wavelengths (wavelength: 405 nm, wavelength: 650 nm, wavelength: 780 nm) was evaluated according to the following method. The results are shown in the following Tables 1 and 2.

### [Measurement of Light Transmittance]

By using each of the foregoing epoxy resin compositions, transfer molding (molding condition: 150° C.×4 minutes) was performed, and furthermore, after curing was performed under a condition at 150° C. for 3 hours, thereby preparing a specimen (disk-shaped cured product) having a diameter of 50 mm and a thickness of 1 mm. This specimen was used for the measurement while dipping in liquid paraffin. A spectrophotometer UV3101, manufactured by Shimadzu Corporation was used as an measurement instrument, and a light transmittance at each of wavelengths (wavelength: 405 nm, wavelength: 650 nm, wavelength: 780 nm) was measured under each of temperature conditions (at 23° C. and 70° C.).

TABLE 1

| | | Example (parts by weight) | | | | | |
|---|---|---|---|---|---|---|---|
| | | 1 | 2 | 3 | 4 | 5 | 6 |
| Epoxy resin | | 100 | 100 | 100 | 100 | 100 | 100 |
| Acid anhydride | | 151 | 151 | 151 | 151 | 151 | 151 |
| Curing accelerator | | 2 | 2 | 2 | 2 | 2 | 2 |
| Silicone compound | | 20 | 20 | 20 | 20 | 20 | 20 |
| Inorganic filler a (silica powder) | | 9 | 9 | 4 | 37 | 0.36 | 37 |
| Inorganic filler b (glass powder) | | — | — | 4 | — | — | — |
| Inorganic filler c (glass powder) | | 25 | 18 | — | 9 | 25 | 224 |
| Refractive index difference *1 | | 0.06 | 0.06 | 0.06 | 0.06 | 0.06 | 0.06 |
| Refractive index difference *2 | | 0.01 | 0.01 | 0.04 | 0.01 | 0.01 | 0.01 |
| Maximum refractive index difference between inorganic fillers | | 0.07 | 0.07 | 0.10 | 0.07 | 0.07 | 0.07 |
| Light transmittance (%) at a wavelength of 405 nm | at 23° C. | 12.3 | 11.9 | 11.8 | 0.6 | 17.4 | 0.5 |
| | at 70° C. | 14.6 | 13.9 | 14.1 | 0.7 | 19.9 | 0.6 |
| (Light transmittance at 23° C.) − (Light transmittance at 70° C.) | | −2.3 | −2.0 | −2.3 | 0.1 | 2.5 | 0.1 |
| Light transmittance (%) at a wavelength of 650 nm | at 23° C. | 32.7 | 33.6 | 33.1 | 4.4 | 50.3 | 4.0 |
| | at 70° C. | 33.8 | 34.0 | 33.9 | 4.5 | 51.9 | 4.1 |
| (Light transmittance at 23° C.) − (Light transmittance at 70° C.) | | −1.1 | −0.4 | −0.8 | 0.1 | 1.6 | 0.1 |
| Light transmittance (%) at a wavelength of 780 nm | at 23° C. | 42.0 | 43.5 | 43.8 | 8.1 | 63.4 | 8.0 |
| | at 70° C. | 42.3 | 43.8 | 44.0 | 8.2 | 63.8 | 8.0 |

| | | | | | | |
|---|---|---|---|---|---|---|
| (Light transmittance at 23° C.) − (Light transmittance at 70° C.) | −0.3 | −0.3 | −0.2 | 0.1 | 0.4 | 0 |

*1: (Refractive index of cured product obtained from organic ingredients) − (Refractive index of inorganic filler a)
*2: (Refractive index of inorganic filler b or c) − (Refractive index of cured product obtained from organic ingredients)

TABLE 2

| | | Comparative Example (parts by weight) | | | | | |
|---|---|---|---|---|---|---|---|
| | | 1 | 2 | 3 | 4 | 5 | 6 |
| Epoxy resin | | 100 | 100 | 100 | 100 | 100 | 100 |
| Acid anhydride | | 151 | 151 | 151 | 151 | 151 | 151 |
| Curing accelerator | | 2 | 2 | 2 | 2 | 2 | 2 |
| Silicone compound | | 20 | 20 | 20 | 20 | 20 | 20 |
| Inorganic filler a (silica powder) | | 9 | 25 | — | — | — | — |
| Inorganic filler b (glass powder) | | — | — | — | — | 9 | 25 |
| Inorganic filler c (glass powder) | | — | — | 9 | 25 | — | — |
| Refractive index difference *1 | | — | — | — | — | — | — |
| Refractive index difference *2 | | — | — | — | — | — | — |
| Maximum refractive index difference between inorganic fillers | | — | — | — | — | — | — |
| Light transmittance (%) at a wavelength of 405 nm | at 23° C. | 11.7 | 1.2 | 93.7 | 92.2 | 58.6 | 53.2 |
| | at 70° C. | 15.3 | 13.9 | 91.2 | 82.4 | 57.0 | 47.5 |
| (Light transmittance at 23° C.) − (Light transmittance at 70° C.) | | −3.6 | −0.4 | 2.5 | 9.8 | 1.54 | 5.7 |
| Light transmittance (%) at a wavelength of 650 nm | at 23° C. | 35.1 | 6.5 | 94.9 | 89.3 | 69.3 | 53.8 |
| | at 70° C. | 41.2 | 9.2 | 90.6 | 77.1 | 66.1 | 46.4 |
| (Light transmittance at 23° C.) − (Light transmittance at 70° C.) | | −6.1 | −2.7 | 4.3 | 12.2 | 3.1 | 7.4 |
| Light transmittance (%) at a wavelength of 780 nm | at 23° C. | 45.5 | 11.9 | 95.6 | 89.9 | 74.1 | 56.4 |
| | at 70° C. | 51.5 | 16.0 | 91.5 | 78.6 | 71.0 | 49.4 |

| | | | | | | |
|---|---|---|---|---|---|---|
| (Light transmittance at 23° C.) − (Light transmittance at 70° C.) | −6.0 | −4.2 | 4.0 | 11.3 | 3.1 | 7.1 |

*1: (Refractive index of cured product obtained from organic ingredients) − (Refractive index of inorganic filler a)
*2: (Refractive index of inorganic filler b or c) − (Refractive index of cured product obtained from organic ingredients)

From the foregoing results, it is clear that in all of the Examples, the fluctuation in light transmittance at each of 23° C. and 70° C. is small over from an ultraviolet light region to a visible light region.

On the other hand, there were obtained the results in which in all of the Comparative Examples, the fluctuation in light transmittance at each of 23° C. and 70° C. is large over from an ultraviolet light region to a visible light region as compared with that in the Examples.

Furthermore, as a comparative example, instead of using the inorganic fillers of a to c, an epoxy resin composition using a methacryl-styrene copolymer filler (high-refractive index filler) and a fluorine-added methacryl-styrene copolymer filler (low-refractive index filler) was prepared and attempted to be subjected to the foregoing measurement test of light transmittance. As a result, the foregoing organic fillers were softened and melted at the transfer molding, and a specimen for the measurement could not be prepared, so that the resulting epoxy resin composition could not be subjected to the measurement test of light transmittance.

While the invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2010-130344 filed on Jun. 7, 2010, and the contents are incorporated herein by reference.

All references cited herein are incorporated by reference herein in their entirety.

Also, all the references cited herein are incorporated as a whole.

The epoxy resin composition of the invention is useful as an encapsulating material for optical semiconductor elements such as a light emitting device (LED), a sensor of every sort and a charge coupling device (CCD), and furthermore, it is able to be used as a reflector forming material such as a reflector of the foregoing LED.

What is claimed is:

1. An epoxy resin composition for optical use, comprising the following ingredients (A) to (C):
(A) an epoxy resin;
(B) a curing agent; and
(C) an inorganic filler comprising (c1) an inorganic filler having a refractive index larger than a refractive index of a cured product obtained from the ingredients of the epoxy resin composition excluding the (C) inorganic filler and (c2) an inorganic filler having a refractive index smaller than the refractive index of the cured product obtained from the ingredients of the epoxy resin composition excluding the (C) inorganic filler.

2. The epoxy resin composition for optical use according to claim 1, wherein the inorganic filler (C) is an inorganic filler comprising (c1) an inorganic filler having a refractive index larger by from 0.01 to 0.10 than the refractive index of the cured product obtained from the ingredients of the epoxy resin composition excluding the (C) inorganic filler and (c2) an inorganic filler having a refractive index smaller by from 0.02 to 0.15 than the refractive index of the cured product obtained from the ingredients of the epoxy resin composition excluding the (C) inorganic filler.

3. The epoxy resin composition for optical use according to claim 1, wherein a maximum refractive index difference among the plural inorganic fillers constituting the inorganic filler (C) is 0.15 or less.

4. The epoxy resin composition for optical use according to claim 1, wherein a mixing weight ratio of the inorganic filler (c1) and the inorganic filler (c2) is from 17/83 to 80/20 in terms of (c1)/(c2).

5. The epoxy resin composition for optical use according to claim 2, wherein the inorganic filler (c1) having a refractive index larger by from 0.01 to 0.10 than the refractive index of the cured product obtained from the ingredients of the epoxy resin composition excluding the (C) inorganic filler is a glass powder; and the inorganic filler (c2) having a refractive index smaller by from 0.02 to 0.15 than the refractive index of the cured product obtained from the ingredients of the epoxy resin composition excluding the (C) inorganic filler is a silica powder.

6. The epoxy resin composition for optical use according to claim 1, wherein a use temperature region of the epoxy resin composition for optical use is from −40 to 150° C.

7. The epoxy resin composition for optical use according to claim 1, the inorganic filler (c1) having a refractive index larger than a refractive index of the cured product obtained from the ingredients of the epoxy resin composition excluding the (C) inorganic filler is a glass powder.

8. The epoxy resin composition for optical use according to claim 1, the inorganic filler (c2) having a refractive index smaller than the refractive index of the cured product obtained from the ingredients of the epoxy resin composition excluding the (C) inorganic filler is a silica powder.

9. An optical component obtained by curing the epoxy resin composition for optical use according to claim 1.

10. An optical semiconductor device manufactured by subjecting an optical semiconductor element to resin encapsulation using the epoxy resin composition for optical use according to claim 1.
